(19) United States
(12) Patent Application Publication
(10) Pub. No.: US 2026/0135521 A1
(43) Pub. Date: May 14, 2026

(54) FAULT PROTECTION CIRCUITS AND METHODS

(71) Applicant: Texas Instruments Incorporated, Dallas, TX (US)

(72) Inventors: Pourya Assem, Dallas, TX (US); Zejian Wang, Shanghai (CN); Ying Xie, Shanghai (CN); Bincheng Cheng, Shanghai (CN); Kannan Krishna, Dallas, TX (US); Jianquan Liao, Shanghai (CN); Qinfang Shen, Dallas, TX (US)

(21) Appl. No.: 19/287,103

(22) Filed: Jul. 31, 2025

Related U.S. Application Data
(60) Provisional application No. 63/719,792, filed on Nov. 13, 2024.

(51) Int. Cl. H03F 1/30; H03F 1/02; H03F 1/52; H03F 3/217

(52) U.S. Cl. CPC H03F 1/301; H03F 1/0255; H03F 1/523; H03F 3/2171; H03F 2200/03; H03F 2200/291; H03F 2200/336; H03F 2200/474; H03F 2203/21142

(57) ABSTRACT

In one example, an apparatus comprises a transistor, a switch, and a control circuit. The transistor has a first current terminal, a second current terminal, and a transistor control terminal. The switch is coupled between the transistor control terminal and a reference terminal, the switch having a switch control input. The control circuit has a control input and a control output, the control output coupled to the switch control input, and the control input coupled to at least one of the transistor control terminal, the first current terminal, or the second current terminal.

### CROSS-REFERENCE TO RELATED APPLICATION

This nonprovisional application is a continuation of U.S. Patent Application No. 63/666,730, filed Jul. 2, 2024, which is hereby incorporated by reference in its entirety.

### BACKGROUND

An electronic device may include high speed electronic components having high frequency switching events and low speed electronic components that do not have high frequency switching events or otherwise operate at a lower frequency. Switching noise may be coupled from the high speed electronic components to the low speed electronic components, and the switching noise may adversely affect the operation of the low speed electronic components.

### SUMMARY

In one example, an apparatus comprises a transistor, a switch, and a control circuit. The transistor has a first current terminal, a second current terminal, and a transistor control terminal. The switch is coupled between the transistor control terminal and a reference terminal, the switch having a switch control input. The control circuit has a control input and a control output, the control output coupled to the switch control input, and the control input coupled to at least one of the transistor control terminal, the first current terminal, or the second current terminal.

In one example, an apparatus comprises an amplifier, a first power stage, a second power stage, a modulator, and a clamp circuit. The amplifier has an amplifier input and an amplifier output. The first power stage has a first power stage input and a first power stage output, the first power stage input coupled to the amplifier output. The clamp circuit is coupled between the first power stage input and a reference terminal, the clamp circuit having a clamp control input coupled to the first power stage. The modulator has a modulator input and a modulator output, the modulator input coupled to the amplifier input. The second power stage has a second power stage input and a second power stage output, the second power stage input coupled to the modulator output;

### BRIEF DESCRIPTION OF THE DRAWINGS

FIGS. 1A and 1B are schematics illustrating examples of an audio system.

FIGS. 2 and 3 are schematics illustrating additional examples of the audio system of FIGS. 1A and 1B.

FIG. 4 is a schematic illustrating examples of switching noise coupling in an audio system.

FIGS. 5A and 5B include graphs illustrating examples of effects of switching noise coupling in an audio system.

FIG. 6 is a schematic illustrating an example of a clamp circuit to mitigate the effect of switching noise.

FIG. 7 is a schematic illustrating examples of internal components of the clamp circuit of FIG. 6.

FIGS. 8 and 9 are schematics illustrating examples of a clamp circuit to mitigate the effect of switching noise.

FIGS. 10A, 10B, and 10C are schematics illustrating examples of a clamp circuit to mitigate the effect of switching noise.

FIG. 11 is a schematic illustrating examples of internal components of the clamp circuits of FIGS. 6-10C.

FIG. 12 includes graphs illustrating examples of operations of the clamp circuit of FIGS. 6-10C.

FIG. 13 is a flowchart illustrating an example method of clamping a transistor.

### DETAILED DESCRIPTION

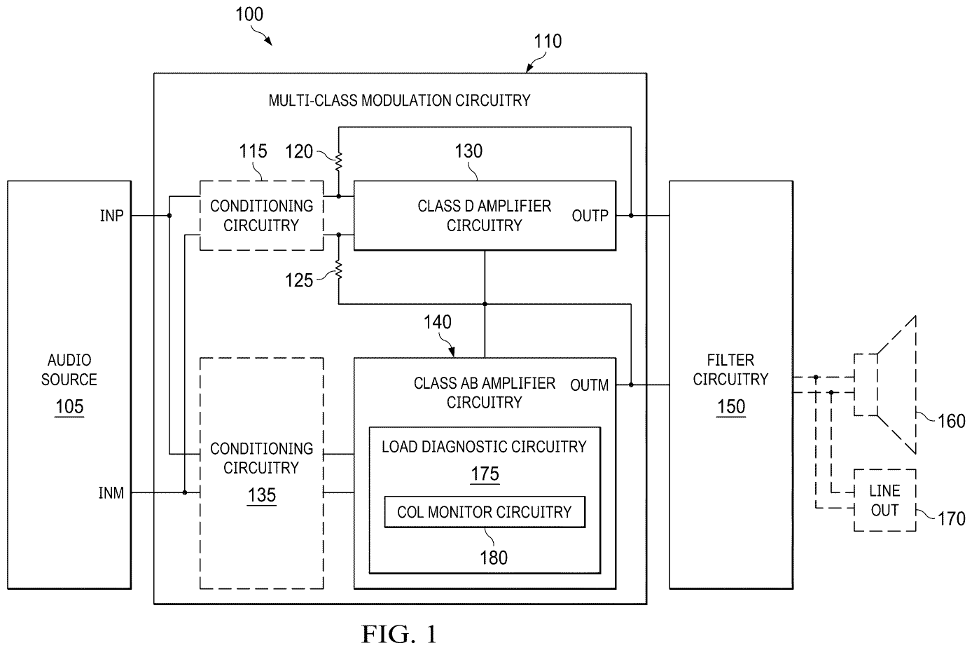

FIG. 1A illustrates an example audio system 100. As shown, system 100 includes a first amplifier (labelled amplifier A) and a second amplifier (labelled amplifier B) driving speaker 102. Amplifier A can be coupled to terminal 104 of speaker 102, and amplifier B can be coupled to terminal 106 of speaker 102. Amplifiers A and B can be of different types with different control schemes. For example, amplifier A can be of a non-switching type, and amplifier B can be of a switching type.

A switching amplifier includes a power stage that generates a multilevel signal (e.g., a binary signal, a trilevel signal, etc.) by selectively connecting the power stage output to one of multiple voltage sources. In some examples, a switching amplifier may operate as a class D amplifier. The switching amplifier may be driven by a modulating circuit that receives a sinusoidal audio signal and generates pulse width modulated (PWM) signals, pulse density signals, and/or any other type of modulated control signals to control the power stage to also generate a modulated signal having discrete signal levels (e.g., binary, ternary, etc.). The modulated signal provided by the power stage can have a timing property, such as duty cycle, pulse width, etc., modulated/varied to reflect an instantaneous amplitude of the audio signal. The modulated signal generated by the power stage can be filtered (e.g., by a low pass filter, or by the inductance of a speaker) to generate an amplified version of the sinusoidal audio signal, and the amplified sinusoidal audio signal can be fed to the speaker. The low pass filter may include an LC filter including a series inductor coupled between the output of the switching amplifier and the speaker, and a shunt capacitor coupled between the speaker and the ground. The low pass filter may also include a capacitor coupled across terminals of the speaker.

A non-switching amplifier may include another power stage driven by a control circuit including a linear amplifier. The control circuit can receive a sinusoidal audio signal, and provide control signals having magnitudes that varies (e.g., linearly or closed to be linearly) according to an instantaneous magnitude of the audio signal to the non-switching amplifier. Responsive to the control signals, the non-switching amplifier can also generate an analog signal having a magnitude that can track the audio signal when the non-switching amplifier operates in a linear mode where the analog signal voltage level is below the supply voltage of the power stage. In a case where the analog signal voltage level is above the supply voltage, the non-switching amplifier may operate in a saturation mode where the analog signal is clipped and limited at the supply voltage. In some examples, the non-switching amplifier may operate as a class A amplifier, a class B amplifier, a class AB amplifier, etc. The output of the non-switching amplifier can also be filtered (e.g., by another low pass filter) to attenuate high frequency components (e.g., noise) and distortions caused by, for example, saturation/clipping, non-linear effects such as distortions at conduction angle hand-over, etc. But because the signal output by the non-switching amplifier is in analog and continuous form, the low pass filter can have fewer components. For example, instead of an LC filter, an audio system can include a capacitor at the non-switching amplifier output to perform the filtering.

FIG. 1B illustrates examples of internal components of system 100 of FIG. 1A. The system 100 of FIG. 1B includes a first power stage PS1 having a first output terminal 108, and a second power stage PS2 having a second output terminal 110. First power stage PS1 can represent (or can be part of) amplifier A of FIG. 1A, and second power stage PS2 can represent (or can be part of) amplifier B of FIG. 1A. The first output terminal 108 and the second output terminal 110 are coupled to a LC filter circuit 112. Two speaker terminals 104 and 106 (also described with respect to FIG. 1A) of the LC filter circuit 112 are coupled to the speaker 102.

Power stage PS1 comprises a first transistor S1 and a second transistor S2 coupled in series between a power terminal 116a (e.g., receiving a power supply PVDD) and a ground terminal. For example, a first current terminal of the transistor S1 is coupled to the power terminal 116a, and a second current terminal of the transistor S1 is coupled to the output terminal 108. A first current terminal of the transistor S2 is coupled to the output terminal 108, and a second current terminal of the transistor S2 is coupled to the ground terminal.

The transistor S1 further includes a control terminal coupled to a first power stage input that receives a control signal CS1 from a driver D1, and the transistor S2 includes a control terminal coupled to a second power stage input that receives a control signal CS2 from another driver D2. The transistors S1 and S2 can set the VN voltage at output terminal 108 of power stage PS1 responsive to control signals CS1 and CS2. In FIG. 1B, power stage PS1 can be controlled as a non-switching amplifier (e.g., class AB, class A, etc.), where CS1 and CS2 can each have a magnitude that varies (e.g., linearly or closed to be linearly) according to an instantaneous magnitude of an audio signal. For example, during a first half cycle of an audio signal, the transistor S1 is on or enabled, the transistor S2 is off or disabled, the transistor S1 can vary a magnitude of the VN voltage based on a magnitude of CS1, which can reflect/track an instantaneous magnitude of the audio signal (if operating in linear mode) during the first half cycle. Also, during a second half cycle of the audio signal, the transistor S1 is off or disabled, the transistor S2 is on or enabled, and the transistor S2 can vary a magnitude of the VN voltage based on a magnitude of CS2, which can also reflect/track an instantaneous magnitude of the audio signal during the second half cycle (if operating in linear mode). In a case where the audio signal is a sinusoidal signal, the VN voltage can be (or close to be) an amplified version of the sinusoidal signal, and the VN voltage can have a same frequency as the audio signal. On the other hand, the audio signal may also saturate power stage PS1, in which case the VN voltage may be clipped at the PVDD voltage or at the ground voltage.

Also, power stage PS2 comprises a third transistor S3 and a fourth transistor S4 coupled in series between a power terminal 116b (e.g., receiving a power supply PVDD) and a ground terminal. In an example, the power terminals 116a and 116b may be a same power terminal shared by both the power stages PS1 and PS2 (or the power terminals 116a and 116b may be coupled to a common power terminal), whereas in another example the power terminals 116a and 116b can be coupled to different voltage sources.

As illustrated, a first current terminal of the transistor S3 is coupled to the power terminal 116b, and a second current terminal of the transistor S3 is coupled to the output terminal 110 having a voltage of VY. A first current terminal of the transistor S4 is coupled to the output terminal 110, and a second current terminal of the transistor S4 is coupled to the ground terminal.

The transistor S3 further includes a control terminal coupled to a third power stage input that receives a control signal CS3 from a driver D3, and the transistor S4 further includes a control terminal coupled to a fourth power stage input that receives a control signal CS4 from another driver D4. The transistors S3 and S4 can set the voltage VY at output terminal 110 of power stage PS2 responsive to control signals CS3 and CS4.

In FIG. 1B, power stage PS2 can be controlled as a switching amplifier (e.g., class D), where control signals CS3 and CS4 are pulse width modulated signals, pulse density signals, and/or any other type of modulated control signals having binary magnitudes. Depending on the magnitude of the audio signal, one of transistors S3 or S4 can be turned on to connect one of power terminal 116b or ground terminal to output terminal 110. Responsive to CS3 and CS4, power stages PS2 can also generate a modulated signal. The modulated signal provided by the power stage can have a timing property, such as duty cycle, pulse width, etc., modulated/varied to reflect an instantaneous magnitude of the audio signal. The transistors S3 and S4 can provide VY as a modulated signal at output terminal 110 responsive to CS4. The modulated signal VY at output terminal 110 can have a much higher frequency than the audio signal as well as the signal VN at output terminal 108.

In FIG. 1B, the transistors S1, S2, S3, and S4 are illustrated as n-channel metal oxide semiconductor (NMOS) field effect transistors (FETs). In other examples, the transistors S1, S2, S3, and S4 can be other types of transistors, such as p-channel MOSFET (PMOS), laterally-diffused metal-oxide semiconductor (LDMOS) FETs, Gallium Nitride (GaN) FETs, NPN or PNP bipolar junction transistor (BJT), etc.

The LC filter circuit 112 includes an inductor L1 coupled between the output terminal 110 and the speaker terminal 106, a capacitor C1 coupled between the speaker terminals 104 and 106, and another capacitor C2 coupled between the speaker terminal 104 and the ground terminal. The inductor L1 and capacitor C1 filter the modulated signal VY provided at the output terminal 110 into a sinusoidal signal VP at the speaker terminal 106 that is output to the speaker 102 to output corresponding audio. Capacitor C2 can also filter signal VN to further suppress non-linearities in the signal VN, and to provide a virtual ground with a relatively low impedance. Capacitor C2 may be relatively large (e.g., 200 nF or larger) to provide a low impedance virtual ground and reduce electromagnetic interference (EMI) and harmonic distortion in the signal VN (e.g., harmonic distortion caused by non-linear conduction angle hand-over in the power stage), as explained in related application U.S. application Ser. No. 18/385,848, entitled “METHODS AND APPARATUS TO MODULATE SIGNALS USING MULTI-CLASS MODULATION CIRCUITRY”, Attorney Docket Number T103189US01. The power stages may drive a current from few micro amps to several amps to charge up capacitor C2.

System 100 also includes a control circuit (not shown in FIG. 1B) that generates control signals that respectively drives the driver circuits D1, D2, D3, D4 based on audio signals. Example operations of system 100 are described in related U.S. application Ser. No. 17/402,264, entitled “Methods and Apparatus to Generated a Modulation Protocol to Output Audio,” filed on Aug. 13, 2021, and related U.S. application Ser. No. 17/491,133, entitled “Switching amplifier having linear transition totem pole modulation,” filed on Sep. 30, 2021, and in U.S. application Ser. No. 18/358,848, which are hereby incorporated by reference in their entireties as described above.

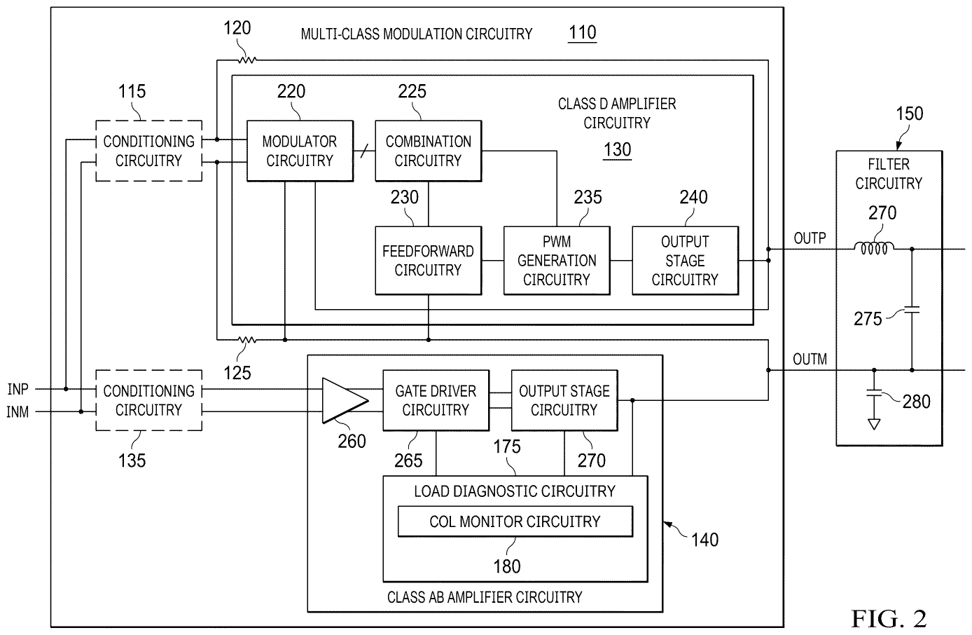

FIG. 2 illustrates examples of internal components of system 100. FIG. 2 illustrates that system 100 includes, in addition to power stages PS1 and PS2, a control circuit 202 that provides the control signals CS1 and CS2 to power stage PS1, and a control circuit 204 that provides the control signals CS3 and CS4 to power stage PS2. During startup and shutdown, both control circuits 202 and 204 may not receive an audio signal 206. During normal operation, control circuits 202 and 204 may receive audio signal 206.

In the example of FIG. 2, control circuit 202 can control power stage PS1 to operate as a non-switching amplifier (e.g., a class AB amplifier). Control circuit 202 can include a linear amplifier to generate control signals CS1 and CS2 by amplifying audio signal 206 (if present). Power stage PS1 can provide a VN voltage at first output terminal 108 having a magnitude that tracks audio signal 206. The VN voltage can also be saturated/clamped if the magnitude of audio signal 206 exceeds a certain threshold. Also, control circuit 204 can control power stage PS2 to operate as a switching amplifier (e.g., a class D amplifier). Control circuit 204 can include modulated signal generator to generate control signals CS3 and CS4 as modulated signals. In some examples, control circuit 204 can include a pulse width modulation (PWM) signal generator to generate control signals CS3 and CS4 as PWM signals, where the pulse width of CS3 and CS4 can be modulated based on an instantaneous amplitude of audio signal 206. The difference between VN and VP, after VN and VP being filtered by the LC filter circuit 112, can become an amplified audio signal.

As shown in FIG. 2, to further improve the matching between the common mode voltages between VN and VP, PS1 control circuit 202 and PS2 control circuit 204 can operate in a master-slave configuration. In the master-slave configuration, PS1 control circuit 202 and power stage PS1 is a master, and PS2 control circuit 204 and power stage PS2 is a slave. Specifically, PS1 control circuit can drive power stage PS1 based on audio signal 206 (if present), or other signals. On the other hand, PS2 control circuit 204 can include a subtraction circuit 210 (e.g., an amplifier) that receives VN and VP (or a filtered version of VY) as feedback signals and generates a difference signal 212 representing a difference between VN and VP. PS2 control circuit 204 can adjust control signals CS3 and CS4 (and VY/VP) based on difference signal 212. For example, PS2 control circuit 204 can adjust control signals CS3 and CS4 to minimize (or reduce) difference signal 212, to improve the matching between the common mode voltages of VN and VP. PS2 control circuit 204 can have a higher bandwidth than PS1 control circuit 202, which allows PS2 control circuit 204 to adjust CS3 and CS4 responsive to both audio signal 206 and difference signal 212.

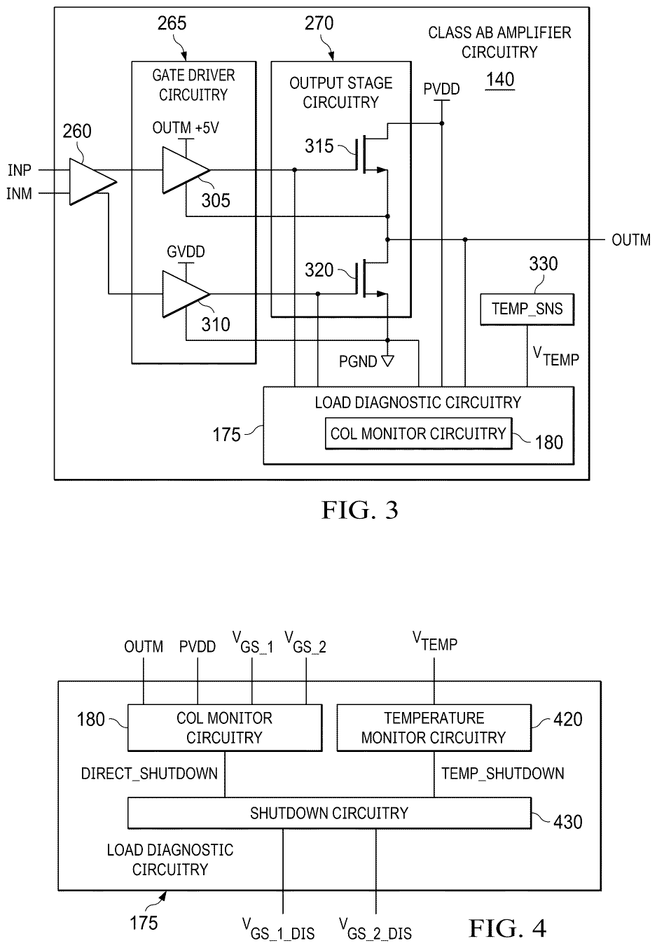

FIG. 3 illustrates examples of internal components of system 100 of FIG. 2. Referring to FIG. 3, system 100 can include an audio driver circuit 300 having driver inputs 302a, 302b, and driver outputs 304a and 304b. The driver outputs 304a and 304b are coupled to, respectively, the inputs of power stages PS1 and PS2. Audio driver circuit 300 includes PS1 control circuit 202 and PS2 control circuit 204. System 100 also includes audio inputs 306a and 306b to receive differential audio signals 206a (also labelled VINP) and 206b (also labelled VINM) of sinusoidal audio signals 206. In some examples, system 100 also includes an audio signal generation circuit 305 to provide the differential audio signals 206a/206b to audio inputs 306a and 306b. Audio signal generation circuit 306 can include a digital to analog converter (DAC) to convert a sequence of digital signals into differential audio signals 206a/206b.

PS1 control circuit 202 includes an amplifier 308 coupled to audio inputs 306a and 306b. In some examples, amplifier 308 can be a linear differential amplifier 308. Amplifier 308 can receive differential audio signals 206a and 206b, and provide control signals CS1 and CS2 by amplifying audio signals 206a and 206b to set VN voltage at first output terminal 106.

Also, PS2 control circuit 204 includes a filter 320 (e.g., a loop filter), a subtraction circuit 322, a subtraction circuit 324, a periodic ramp generator 326, a comparator 328, and a voltage scaler circuit 329. Subtraction circuit 322, subtraction circuit 324, and voltage scaler circuit 329 are collectively part of a signal combination circuit 325. In some examples, filter 320 can include a multi-stage loop filter. Voltage scaler circuit 329 provides a scaled down version of the VN voltage as a feedback signal 330. Voltage scaler circuit 329 can also remove the common mode/DC bias component of the VN voltage, and provide a scaled down version of the AC (alternating current) component of the VN voltage. Also, subtraction circuit 322 can generate a difference signal 332 representing a difference between filtered audio signals 206a and 206b and feedback signals through resistors 350b and 352b, where the difference signal 332 can have an opposite polarity from the VN voltage (and feedback signal 330). Further, subtraction circuit 324 can generate another difference signal 334 representing a difference between signals 330 and 332. Signal combination circuit 325 can represent subtraction circuit 210 of FIG. 2, and difference signal 334 can represent difference signal 212 of FIG. 2. System 100 can also include a common mode regulator 327 coupled to driver inputs 302a and 302b to define a same input common mode voltage for driver inputs 302a and 302b.

Further, comparator 328 can generate control signals CS3 and CS4 by comparing difference signal 334 with a periodic ramp signal provided by periodic ramp generator 326 and modulating the duty cycle/pulse widths of CS3 and CS4 based on the difference. Periodic ramp generator 326 can receive a clock signal (labelled CLK) and generate the periodic ramp signal synchronized to the clock signal and having a cycle period defined based on the clock signal. Difference signal 334 can have a component representing the audio signals 206 and a corrective component representing the difference between VP and VN caused by, for example, the aforementioned asymmetry and non-linear effects. Accordingly, the duty cycle/pulse widths of CS3 and CS4 can reflect the instantaneous magnitudes of audio signals 206a and 206b (represented by difference signal 332) and a difference between VP and VN (as part of the master-slave configuration), and control circuit 204 can adjust CS3 and CS4 to reduce/minimize the aforementioned difference between VP and VN caused by asymmetry and non-linear effects.

Also, system 100 can also include a pair of resistor networks 350 and 352 to set an overall amplification gain of the system. The overall amplification gain can be between the differential output voltage VP-VN (or VY-VN) and the differential input voltage VINP-VINM. System 100 can include resistor network 350 for the signal path from VINP to VY, and resistor network 352 for the signal path from VINM to VN. Resistor network 350 can include an input resistor 350a coupled between audio input 306a and driver input 302a, and a feedback resistor 350b coupled between driver input 302a and output terminal 110. Also, resistor network 352 can include an input resistor 352a coupled between audio input 306b and driver input 302b, and a feedback resistor 352b coupled between driver input 302b and output terminal 108. Resistor networks 350 and 352 are to be matched, where input resistors 350a and 352a have a same resistance (e.g., RIN) and feedback resistors 350b and 352b have a same resistance (e.g., RFB), to remove a component of differential output voltage VP-VN (or VY-VN) caused by the output common mode voltage VCM, and to provide an amplification gain for the differential input voltage VINP-VINM.

In audio system 100, the output of power stage PS2 is coupled to inductor L1, which can discharge to provide a current to speaker 102 via terminal 106, thereby driving terminal 106 at voltage VP. Accordingly, power stage PS2 may provide a current to charge inductor L1, which can also improve the power efficiency of power stage PS2. In contrast, the output of power stage PS1 is coupled to capacitor C2 and output terminal 108, which is coupled to terminal 104 of speaker 102. Power stage PS1 may provide a current to charge/discharge capacitor C2, and to provide a current to speaker 102 via terminals 104/108, thereby driving terminals 104/108 at the VN voltage.

As described above, in audio system 100, PS1 control circuit 202 including amplifier 308 operates power stage PS1 as a non-switching amplifier, while PS2 control circuit 204, which includes periodic ramp generator 326 and comparator 328, operates power stage PS2 as a switching amplifier. PS2 control circuit 204 provides control signals CS3 and CS4 that toggles between the supply rails of power stage PS1 (e.g., PVDD and ground) and at a high frequency (e.g., the frequency of periodic ramp generator 326) than CS1 and CS2. On the other hand, amplifier 308 provides control signals CS1 and CS2 at a lower frequency (e.g., at the frequency of the audio signal), at a lower slew rate, and having a reduced voltage swing limited by, for example, the output voltage range of amplifier 308 where the transistor devices of amplifier 308 remain in saturation.

The high frequency switching of power stage PS2 can generate switching noise, and the switching noise can be coupled into the control terminals (gates) of the transistors S1 and S2 of power stage PS1 via power supply, ground, capacitor C1 and inductor L1, or any other metal interconnect shared between the power stages PS1 and PS2. Switching noise from other sources may also be coupled into the gates of the transistors S1 and S2 of power stage PS1, which can adversely affect the operation of power stage PS1. Because of, as well as the relatively low bandwidth and low slew rate of amplifier 308, amplifier 308 alone may be unable to adjust the gate voltages of transistors S1 and S2 to compensate for the effect of the switching noise.

FIG. 4 illustrates examples of mechanisms of switching noise generation and coupling in audio system 100. Referring to FIG. 4, power terminal 116a of power stage PS1 and power terminal 116b of power stage PS2 are coupled to a power supply interconnect 402 (e.g., a power plane), which can have a distributed network of parasitic inductances 402a, 402b, 402c, and 402d. Parasitic inductance 402a is between power supply PVDD and power terminal 116b of power stage PS2, parasitic inductance 402b is between PVDD and power terminal 116a of power stage PS1, parasitic inductance 402c is between power terminals 116a and 116b, and parasitic inductance 402d is between power terminal 116a and other systems, such as power stage PS2 of another audio channel, a clock generator, a high frequency digital system, etc. Also, power stages PS1 and PS2 are coupled to a ground interconnect 404 (e.g., a ground plane), which can also have a distributed network of parasitic inductances 404a, 404b, 404c, 404d, 404e, and 404f. Parasitic inductance 404a is between power stage PS2 and ground, parasitic inductance 404b is between power stage PS1 and ground, parasitic inductance 404c is between capacitor C2 and ground, parasitic inductances 404d and 404e are between power stages PS1 and PS2, and parasitic inductance 404f is between power stage PS1 and the aforementioned other systems. Further, there can be parasitic inductance 406 between speaker 102 and output terminal 108 of power stage PS1.

Switching noise can be coupled into the gates of transistor S1 and S2 from various sources. For example, as power stage PS2 operates as a switching amplifier, there can be huge switching current through parasitic inductances 402a and 404a. The switching current can induce voltage transition events 410a and 410b across, respectively, parasitic inductances 402a and 404a. Voltage transition event 410a, in the form of switching noises, can be coupled into the gate of transistor S1 via parasitic inductance 402c and gate-drain parasitic capacitance Cgd1 of transistor S1, and induce a voltage transition event 412 at the gate of transistor S1. Also, voltage transition event 410b, in the form of switching noises, can be coupled into the gate of transistor S2 via parasitic inductances 404e and 404d and gate-source parasitic capacitance Cgs2 of transistor S2, and induce a voltage transition event 414 at the gate of transistor S2. Voltage transition events 410c and 410d can also be coupled into, respectively, the gates of transistors S1 and S2 and contribute to the voltage transition events 412 and 414 via parasitic inductances 402d and 404f. Voltage transition events 410c and 410d can be caused by, for example, switching noise from other parts of the integrated circuit including power stages PS1 and PS2 (e.g., a neighboring channel), switching noise from other components external to the integrated circuit, or within the integrated circuit coupled through the power plane of a printed circuit board (PCB) and parasitic inductance 402a/b. The induction and coupling of these voltage transition events can be examples of ground bounce events. In addition, there can be other switching noise sources, such as the switching of other power stages PS1/PS2, in a case where speaker 102 generates switching noise, and/or in a case where power stage PS1 drives a load that generates switching noise. In all these scenarios, the switching noise (represented by voltage transition event 412) can also be coupled into the gates of transistors S1 and S2 via output terminal 108.

As described above, because of the relatively low bandwidth and slew rate of amplifier 308, amplifier 308 alone may be unable to adjust the gate voltages of transistors S1 and S2 to compensate for the effect of the switching noise. The aforementioned voltage events may inadvertently turn on transistors S1 and S2 when they are to be turned off, or otherwise put transistors S1 and S2 in indeterministic states, which can adversely affect the operation of power stage PS1 and audio system 100.

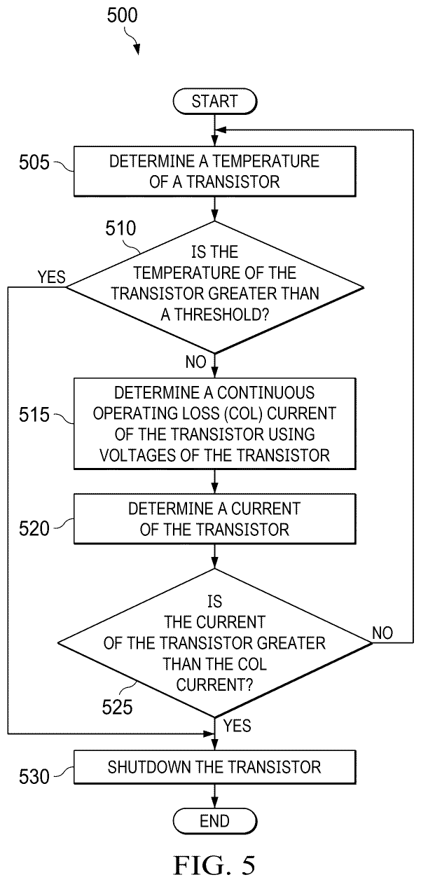

FIG. 5A and FIG. 5B include graphs illustrating example effects of switching noise on the operation of power stage PS1. FIG. 5A includes graphs 502, 504, 506, 508, 510, and 512. Graph 502 illustrates an example variation of the gate voltage of transistor S1 with respect to time. Graph 504 illustrates an example variation of the current conducted by transistor S1 with respect to time. Graph 506 illustrates an example variation of the gate voltage of transistor S2 with respect to time. Graph 508 illustrates an example variation of the current conducted by transistor S2 with respect to time. Graph 510 illustrates an example variation of power consumption (or power loss) at transistor S2 with respect to time. Graph 512 illustrates an example variation of power consumption (or power loss) at transistor S1 with respect to time. FIG. 5B includes zoomed-in view of graphs 502-512 of FIG. 5A.

Referring to FIG. 5A, within an interval T0, which can correspond to a half period of the audio signal, amplifier 308 can provide a high voltage V0 (e.g., around 5V, or the PVDD voltage) at the gate of transistor S1 to turn on transistor S1, and a low voltage V1 (e.g., below or around Vth of transistor S2) at the gate of transistor S2 to turn off transistor S2. The gate voltage of transistor S1 may also track the audio signal until the gate voltage reaches V0. Also, within an interval T1, which can correspond to another half period of the audio signal, amplifier 308 can provide the low voltage V1 (e.g., below or around Vth of transistor S1) to turn off transistor S1. and provide the high voltage V0 (around 5V in FIGS. 5A and 5B) to turn on transistor S2.

Graphs 502 and 506 also show voltage transition events, such as events 502a and 506a, caused by coupling of switching noise from power stage PS2. The voltage transition events and the switching noise can have similar frequency as the switching of power stage PS2, which is much higher than the frequency of the audio signal. Because of the voltage transition events, the gate voltage of transistor S1 can become higher than V1 during significant portions of interval T1 when transistor S1 is to be turned off. Also, the gate voltage of transistor S2 can also become higher than V1 during significant portions of interval T0 when transistor S2 is to be turned off.

The turning on of transistor S1 during interval T1, when transistor S2 is turned on and transistor S1 is to be turned off, and the turning on of transistor S2 during interval T0 when transistor S1 is turned on and transistor S2 is to be turned off, can create a short circuit between PVDD and ground via power stage PS1, which can lead to conduction of a large current through power stage PS1. Also, due to limited bandwidth and slew rate, amplifier 308 may be unable to set the gate voltages of the transistors S1 and S2 back to V1 quickly, and the short circuit can happen within significant portions of interval T0 and T1, which can lead to substantial energy loss. For example, referring to FIG. 5B, which illustrates zoomed-in version of graphs 502-512 within interval T0, the switching noise induce a voltage transition event at the gate of transistor S2 at time T2, and the gate voltage increases from 0V to 2.6V. It takes about 30 nanoseconds (ns) for amplifier 308 to bring down the gate voltage of transistor S2 back to V1 (below or around Vth of transistor S2). Within the 30 ns, a short circuit is created between PVDD and ground via power stage PS1, which lead to huge short circuit current pulses. With a peak power loss of 650 Watts (W), and over 30 ns, a substantial amount of energy can be wasted/lost at power stage PS1. This short circuit can be created even when power stage PS1 is operated in idle mode and not being actively driven by an audio signal. For example, power stage PS1 of an idle channel can be affected by ground bounce events of a neighboring channel. The huge short circuit current pulses can also induce extra ground bounce events by creating huge current transient events through the parasitic inductances shown in FIG. 4.

The high frequency voltage transitions at the gates of transistors S1 and S2 can degrade the performance of audio system 100 in various ways. Specifically, the voltage transitions can lead to substantial power loss, which can degrade the overall power efficiency of audio system 100 and generate substantial heat, which may create safety hazard or at least degrade user experience. Thermal management to mitigate the substantial heat can also be bulky and expensive to the user. Also, the conduction of a large amount of current via transistors S1 and S2 due to the short circuit can shorten the life times of the transistors. Further, in examples where power stage PS1 is coupled to an overcurrent detection circuit, the large current can trigger the overcurrent detection circuit to shut down power stage PS1 and disrupt its operation. Moreover, the high frequency voltage transitions can increase the electromagnetic interference (EMI) signature of audio system 100, which can disrupt the operations of other electronic devices near audio system 100.

One possible way of mitigating the switching noises is providing separate power supply and ground planes for power stage PS1 and power stage PS2. Such arrangements can reduce the coupling of the switching noise from power stage PS2 via the shared power supply plane and/or shared ground plane to power stage PS1, as illustrated in FIG. 4. In examples where power stages PS1 and PS2 are within the same integrated circuit package, additional package interconnects (e.g., pins, pads, etc.), and/or a larger integrated circuit package, may be provided to connect the separate power supply planes and separate ground planes to different power supplies, which can increase package complexity and cost. Also, the bandwidth of amplifier 308 can be increased to shorten the time taken by amplifier 308 to bring down the gate voltage, which can reduce the power loss incurred by the voltage transition events. But the bandwidth and slew rate of amplifier 308 may be increased multifold to effectively shorten the time. Because amplifier 308 drives power stage PS1, which may be large, the power consumption of amplifier 308 may become prohibitively large. Peripheral circuit that drives amplifier 308, such as a charge pump circuit, may also become large and include more expensive external components.

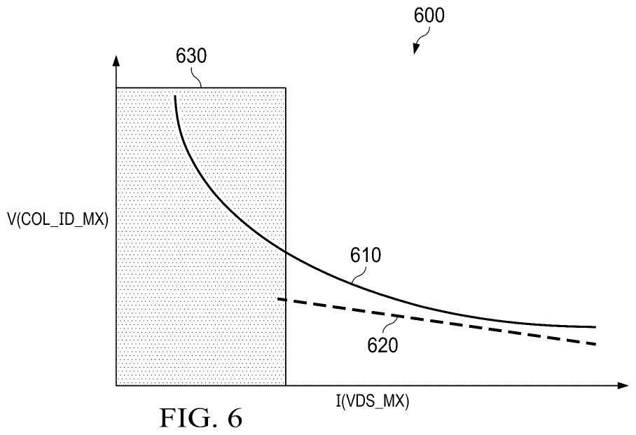

FIG. 6 illustrates an example of a circuit that can address at least some of issues described above. Referring to FIG. 6, audio system 100 can include a clamp circuit 600. Clamp circuit 600 includes a switch 602 (e.g., a transistor) coupled between the control terminal/gate 604a of a transistor 604, which can be one of transistor S1/S2 of power stage PS1, and a reference terminal 606. Reference terminal 606 can receive a reference voltage. When enabled, switch 602 can connect the gate of transistor 604 to reference terminal 606 to adjust the gate voltage by clamping/setting the gate voltage at the reference voltage. As to be described below, in some examples, the reference voltage can be a voltage to turn off transistor 604 (e.g., a ground voltage, a reference voltage based on a voltage at one of current terminals of transistor 604, such as source 604b of transistor 604, etc.). In some examples, the reference voltage can track an average of the gate voltage of transistor 604 (e.g., in the off-state), with the voltage transition events removed or at least attenuated. With such arrangements, the duration of the short circuit via power stage PS1 caused by voltage transition events can be reduced, which can reduce power loss (and the resulting thermal dissipation), improve reliability of the transistor devices of power stage PS1, and reduce the EMI signature of audio system 100. Moreover, switch 602 can be much smaller than transistor 604 (and power stage PS1), which can reduce the amount of power involved in driving switch 602. Accordingly, clamp circuit 600 can have a much higher bandwidth than amplifier 308 in clamping the gate voltage of transistor 604 while consuming limited amount of power. The aforementioned issues with providing separate power supply and ground planes for power stage PS1 and power stage PS2 and increasing the bandwidth/slew rate of amplifier 308 can also be avoided.

Clamp circuit 600 also includes a control circuit 610 that enables/disables switch 602. Control circuit 610 can provide a control signal 611 to enable switch 602 based on detecting a voltage transition event at gate 604a of transistor 604, and disable switch 602 if no voltage transition event is detected. Control circuit 610 can include a voltage transition detection circuit 612 to detect the voltage transition event. As to be described below, control circuit 610 can detect the voltage transition event in various ways, such as by detecting that an instantaneous gate voltage of transistor 604 exceeds an average of the gate voltage over a short time window, by detecting that the edge rate of the gate voltage exceeds a voltage threshold, or by detecting that the current conducted by transistor 604 exceeds a current threshold which indicates a short circuit. Accordingly, voltage transition detection circuit 612 has an input 612a coupled to the gate 604a of transistor 604 or current terminals (e.g., drain terminal 604c and/or source terminal 604b) of transistor 604 to sense the gate voltage and/or current of transistor 604. Voltage transition detection circuit 612 also has an output 612b to provide a voltage transition detection signal 614 to set the state of switch 602.

Also, control circuit 610 includes a maximum voltage detection circuit 622. Maximum voltage detection circuit 622 can detect whether the output voltage of amplifier 308, and the gate voltage of transistor 604, is at or close to a maximum (e.g., the V0 voltage in FIG. 5A). If the gate voltage of transistor 604 is at or close to the maximum, transistor 604 is to be turned on, and the clamping of clamp circuit 600 can be disabled/discontinued to avoid clamping the gate voltage of transistor 604 and therefore disrupting its operation. Accordingly, maximum voltage detection circuit 622 has an input 622a coupled to the gate 604a of transistor 604, and provide a maximum voltage detection signal 624 at an output 622b.

Control circuit 610 also includes a control signal generation circuit 632. Control signal generation circuit 632 has an input 632a coupled to output 622b, an input 632b coupled to output 612b, and an output 632c coupled to a switch control input 602a of switch 602. Control signal generation circuit 632 can receive voltage transition detection signal 614 at input 632a, receive maximum voltage detection signal 624 at input 632b, and provide control signal 611 at output 632c based on voltage transition detection signal 614 and maximum voltage detection signal 624. Specifically, control signal generation circuit 632 can provide control signal 611 at a first state (e.g., a high voltage state) to turn on switch 602 if voltage transition detection signal 614 indicates a voltage transition event and maximum voltage detection signal 624 indicates that the gate voltage of transistor 604 is not at or close to maximum. Control signal generation circuit 632 can also provide control signal 611 at a second state (e.g., a low voltage state) to turn off switch 602 if voltage transition detection signal 614 indicates no voltage transition event, or maximum voltage detection signal 624 indicates that the gate voltage of transistor 604 is at or close to maximum. Control signal generation circuit 632 may also include circuits to speed up the transition of control signal 611 between the first and second states to speed up the enabling and/or disabling of switch 602, which can improve the responsiveness of clamp circuit 600 to the voltage transition events to reduce the durations of the short-circuit intervals, and also to reduce the disruption to the normal operation of transistor 604 due to the clamping operation.

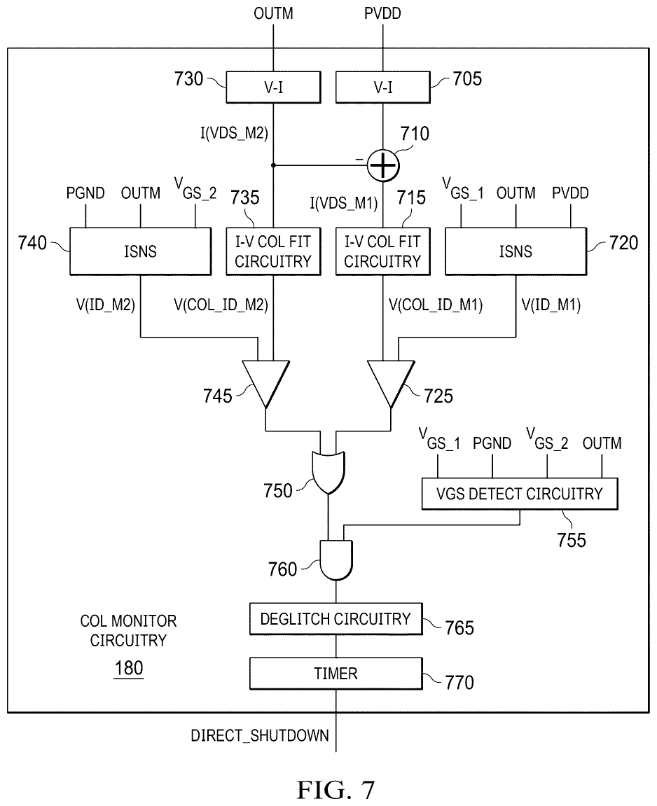

FIG. 7 illustrates examples of internal components of clamp circuit 600. In the example of FIG. 7, reference terminal 606 is coupled to the ground, and input 612a of voltage transition detection circuit 612 is coupled to the gate 604a of transistor 604. Voltage transition detection circuit 612 includes a low pass filter 702 coupled to input 612a to receive an instantaneous gate voltage of transistor 604, which may rise due to the voltage transition events, and generate a time-averaged version of the gate voltage (or an average gate voltage) with the voltage transition events removed or at least attenuated. Voltage transition detection circuit 612 also includes a transistor 704 having a gate coupled to input 612a to receive the instantaneous gate voltage of transistor 604, and a source coupled to low pass filter 702 to receive the time-averaged version of the gate voltage. Transistor 704 is coupled between output 612b and the output of low pass filter 702. Transistor 704 is configured as a comparator and provide voltage transition detection signal 614 based on comparing between the instantaneous gate voltage and the time-averaged version of the gate voltage, so that voltage transition detection signal 614 can indicate whether a voltage transition event is detected at gate 604a of transistor 604. A bias circuit 706 is coupled between output 612b and a power supply terminal 708. Bias circuit 706 includes a capacitor 706a to filter out noise (including switching noise) at the power supply terminal and to provide a bias current and a bias voltage with reduced disturbance to transistor 704. With such arrangements, the voltage transition detection signal 614, and the decision on whether to turn on/off switch 602 to clamp the gate voltage of transistor 604, is generated based on whether voltage transition events occur at gate 604a of transistor 604 but not at other places (e.g., power terminal 708).

Transistor 704 is configured as a comparator and provide voltage transition detection signal 614 based on comparing between the instantaneous gate voltage and the time-averaged version of the gate voltage. For example, if the instantaneous gate voltage, due to the voltage transition event, exceeds the average gate voltage by at least one threshold voltage of transistor 704, transistor 704 can be turned on to bring down the voltage of output 612b to, for example, the average gate voltage. Also, if at the end of a voltage transition event, the difference between the instantaneous gate voltage and the average gate voltage is less than the threshold voltage, or the instantaneous gate voltage falls below the average gate voltage, transistor 704 can be turned off, and bias circuit 706 can pull the output of output 612b to the power supply voltage. Accordingly, the transistor 704 can provide voltage transition detection signal 614 that tracks/indicates a voltage transition event at gate 604a.

Also, control signal generation circuit 632 includes an alternating current (AC) capacitor 710 (or an AC coupled capacitor 710), a metastable buffer 712, and a switch network 714. AC capacitor 710 can perform high pass filtering on voltage transition detection signal 614, and provide the filtered signal 614 to metastable buffer 712. Metastable buffer 712 includes fast trigger metastable circuits 712a and 712b, which can be triggered on both rising and falling edges of detection signal 614, to generate control signal 611 based on the filtered signal 614 and with reduced delay, to improve the responsiveness of clamp circuit 600 in enabling/disabling switch 602. Also, metastable buffer 712 drives (directly or indirectly) switch 602, which can be small compared with transistor 604 as explained above. Accordingly, metastable buffer 712 may consume a small amount of power while operating switch 602 at a high speed. In some examples, metastable buffer 712 can include one of circuits 712a or 712b to be trigger based on rising or falling edge of detection signal 614, followed by a timer to set a pre-determined pulse width of control signal 611, which can further reduce the power consumption of control signal generation circuit 632.

Further, switch network 714 can receive maximum voltage detection signal 624 and can either forward control signal 611 provided by metastable buffer 712 at output 632c if maximum voltage is not detected at gate 604a, or pull down the voltage of output 632c to ground to disable switch 602 if maximum voltage is detected at gate 604a.

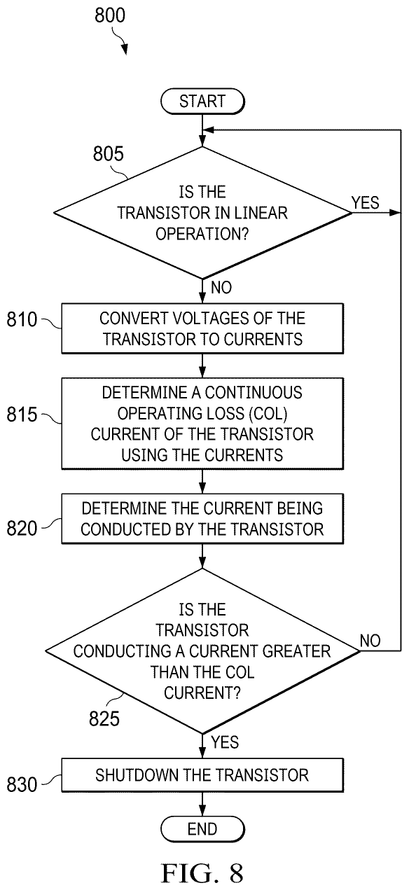

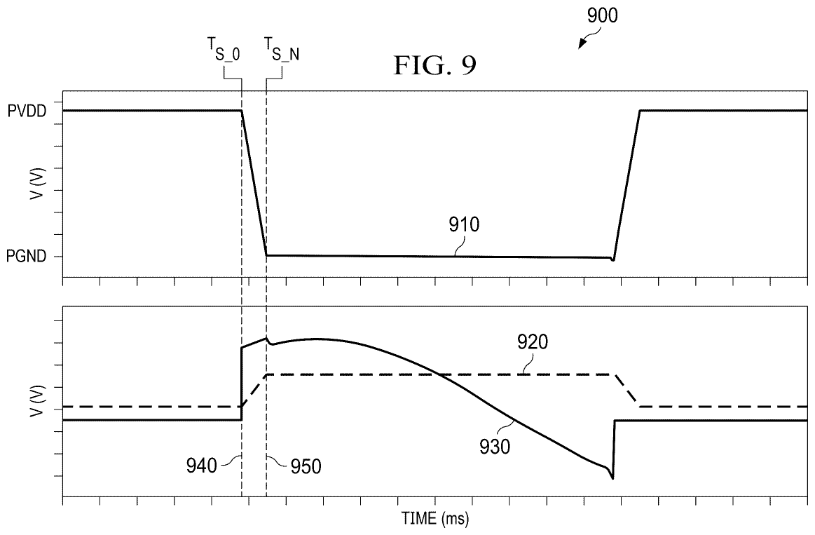

FIG. 8 and FIG. 9 illustrate additional examples of internal components of clamp circuit 600. As shown in FIG. 8, voltage transition detection circuit 612 can include a dv/dt circuit 804 coupled to input 612a, which is coupled to gate 604a of transistor 604, and a comparator 802 coupled between dv/dt circuit 804 and output 612b. The dv/dt circuit 804 can generate a voltage signal representing an absolute edge rate (for both rising and falling edges) of the gate voltage of transistor 604. In some examples, dv/dt circuit 804 can include an AC capacitor to provide a current based on the edge rate of the gate voltage, and a current-to-voltage converter to convert the current to a voltage signal. Comparator 802 can generate voltage transition detection signal 614 by comparing the voltage signal against a voltage threshold 806. Comparator 802 can set voltage transition detection signal 614 to a first state if the voltage signal exceeds the voltage threshold 806, which can indicate the presence of a voltage transition event caused by the coupling of switching noise. Comparator 802 can also set voltage transition detection signal 614 to a second state, which can indicate the absence of (or the end of) the voltage transition event.

Also, as shown in FIG. 9, voltage transition detection circuit 612 can include a current sensor 904 coupled to input 612a, which is coupled to one or more current terminals of transistor 604 (e.g., source terminal 604b, drain terminal 604c), and a comparator 902 coupled between current sensor 904 and output 612b. Current sensor 904 can provide a current sense signal (which can be a voltage signal) representing an amount of current conducted by transistor 604. Comparator 802 can generate voltage transition detection signal 614 by comparing the output of current sensor 904 against a current threshold 906, which can be based on an amount of current conducted by transistor 604 when power stage PS1 provides a short circuit between PVDD and ground. Comparator 902 can set voltage transition detection signal 614 to a first state if the current sense signal exceeds the current threshold 906, which can indicate the presence of a short circuit in power stage PS1 caused by a voltage transition event at gate 604a of transistor 604. Comparator 902 can also set voltage transition detection signal 614 to a second state, which can indicate no short circuit in power stage PS1, which can also indicate the absence of (or the end of) the voltage transition event at gate 604a.

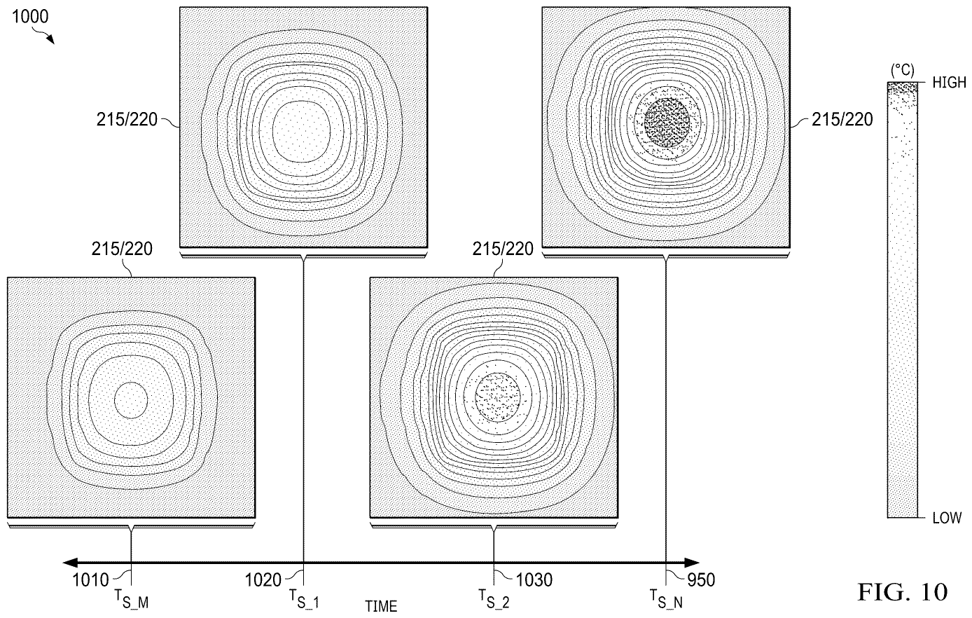

FIGS. 10A, 10B, and 10C illustrate examples of connections of reference terminal 606, which can provide a reference voltage to which the gate voltage of transistor 604 is clamped when switch 602 is enabled. As shown in FIG. 10A, reference terminal 606 can be coupled to ground, so that when switch 602 is enabled, the gate voltage of transistor 604 is set to the ground voltage to turn off transistor 604.

Also, as shown in FIG. 10B, reference terminal 606 can be coupled to source terminal 604c of transistor 604 via a diode-connected transistor 1000, which can track the threshold voltage of transistor 604 across process variations and different temperatures, to provide a reference voltage equal to the threshold voltage above the source voltage of transistor 604. Such arrangements can reduce the voltage difference between the gate and source of transistor 604 during clamping, which can reduce voltage stress and disturbance, and improve reliability of transistor 604. Also, because the gate-source voltage difference of transistor 604 is still below the threshold voltage, transistor 604 can be turned off during clamping to remove the short-circuit current path within power stage PS1. Further, because of the reduced gate-source voltage difference, the driver of amplifier 308 also consumes less power to charge the gate of transistor 604 back to the prior voltage state. This reduces the power handling rating of any peripheral that supplies the power to the driver of amplifier 308.

Further, as shown in FIG. 10C, reference terminal 606 can be coupled to an average generator circuit 1002, which can be similar to low pass filter 702 of FIG. 7 and can be coupled to gate 604a of transistor 604 to generate a time-averaged version of the gate voltage with the voltage transition events removed or at least attenuated. Switch 602 can clamp gate 604a of transistor 604 to the average gate voltage to allow transistor 604 to operate (e.g., providing a current that tracks the audio signal), instead of turning off transistor 604. Also, with the arrangements of FIG. 10C where gate 604a can be clamped to the average gate voltage, which tracks the dynamics of the system, the disturbance to the operation of amplifier 308 can be reduced. The signal quality of amplifier 308 can also be improved due to the reduced disturbance of amplifier 308.

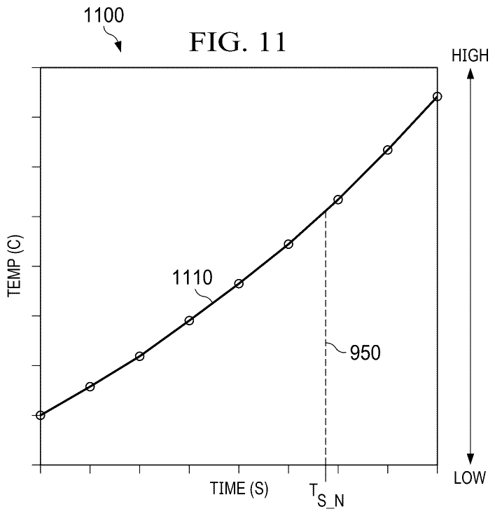

FIG. 11 illustrates examples of internal components of maximum voltage detection circuit 622. Referring to FIG. 11, in some examples, maximum voltage detection circuit 622 includes a comparator 1102 having a negative input coupled to input 622a, which is coupled to gate 604a of transistor 604 and output of amplifier 308. The positive input of comparator 1102 receives a threshold representing a maximum output voltage of amplifier 308. In some examples, as shown in FIG. 11, maximum voltage detection circuit 622 can include a voltage drop circuit 1104 to generate the reference voltage. The reference voltage can be with respect to the transistor 604 source voltage to track the threshold voltage variation of transistor 604 (e.g., due to PVT variations). Voltage drop circuit 1104 can be coupled between a supply voltage of amplifier 308 (e.g., AVDD as shown) and the positive input of comparator 1102. The reference voltage generated by voltage drop circuit 1104 can represent the gate voltage of transistor 604 when transistor 604 is fully turned on, and output terminal 108 is saturated at the PVDD supply voltage of power stage PS1.

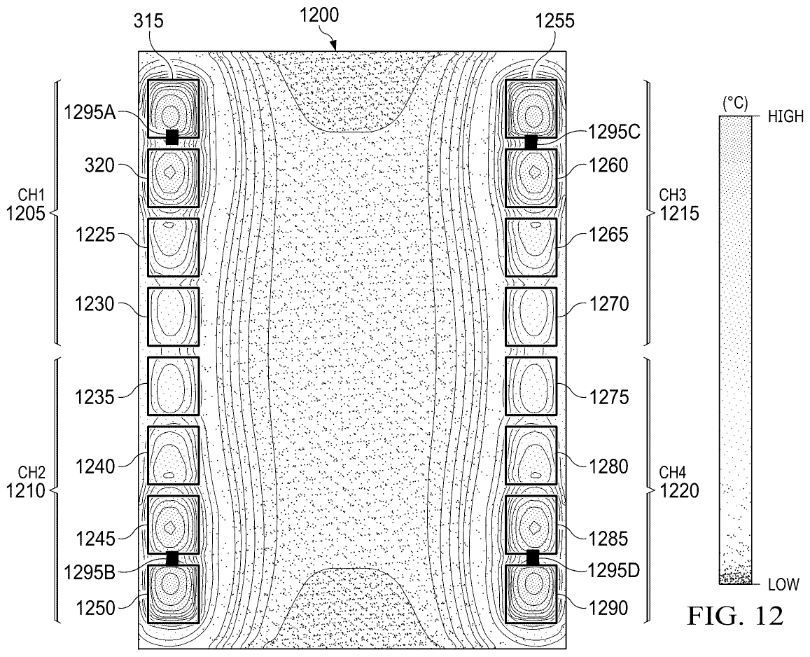

FIG. 12 includes graphs that illustrate examples of operations of clamp circuit 600. FIG. 12 includes graphs 1202, 1204, 1206, 1208, 1210, and 1212. Graph 1202 illustrates an example variation of the gate voltage of transistor S1 with respect to time. Graph 1204 illustrates an example variation of the current conducted by transistor S1 with respect to time. Graph 1206 illustrates an example variation of the gate voltage of transistor S2 with respect to time. Graph 1208 illustrates an example variation of the current conducted by transistor S2 with respect to time. Graph 1210 illustrates an example variation of power consumption (or power loss) at transistor S2 with respect to time. Graph 1212 illustrates an example variation of power consumption (or power loss) at transistor S1 with respect to time. Referring to FIG. 12, clamp circuit 600 detects a voltage transition event at time T2. At time T3′, which is about 7 ns from T2, clamp circuit 600 clamps the gate voltage of transistor S2, thereby disabling the short circuit in power stage PS1 and stops the short-circuit current. Although the peak power loss in FIG. 12 is also 650 W, similar to as shown in FIG. 5B, because of the reduced duration of the short-circuit interval (from 30 ns to 7 ns), the energy loss (and resulting thermal dissipation) caused by the switching noise can be substantially reduced. By reducing the duration of the voltage transition event, the EMI signature can also be substantially reduced as well.

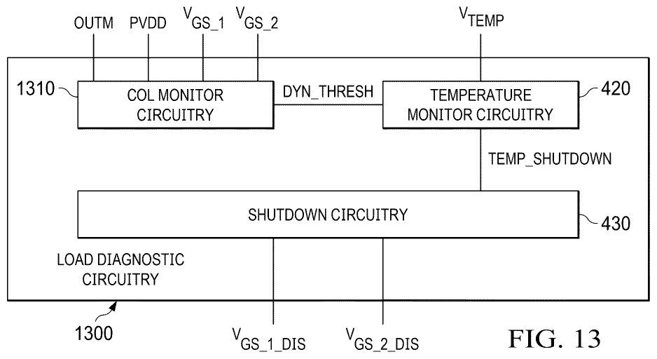

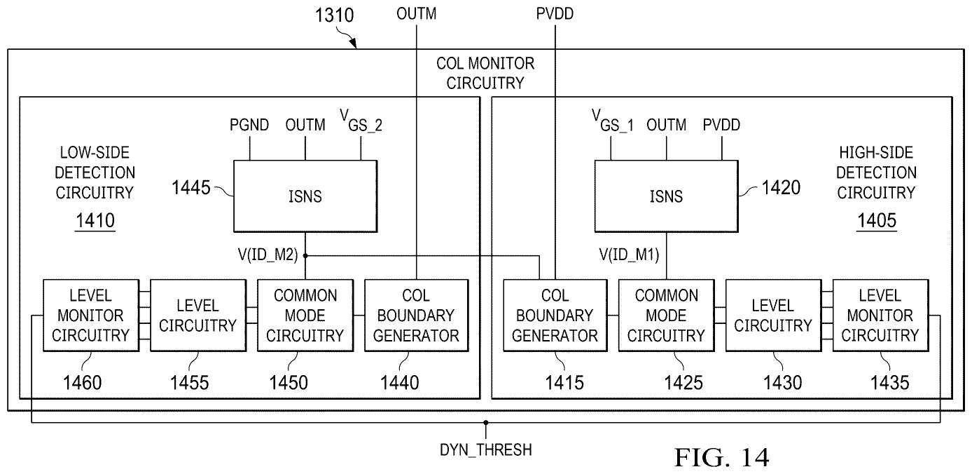

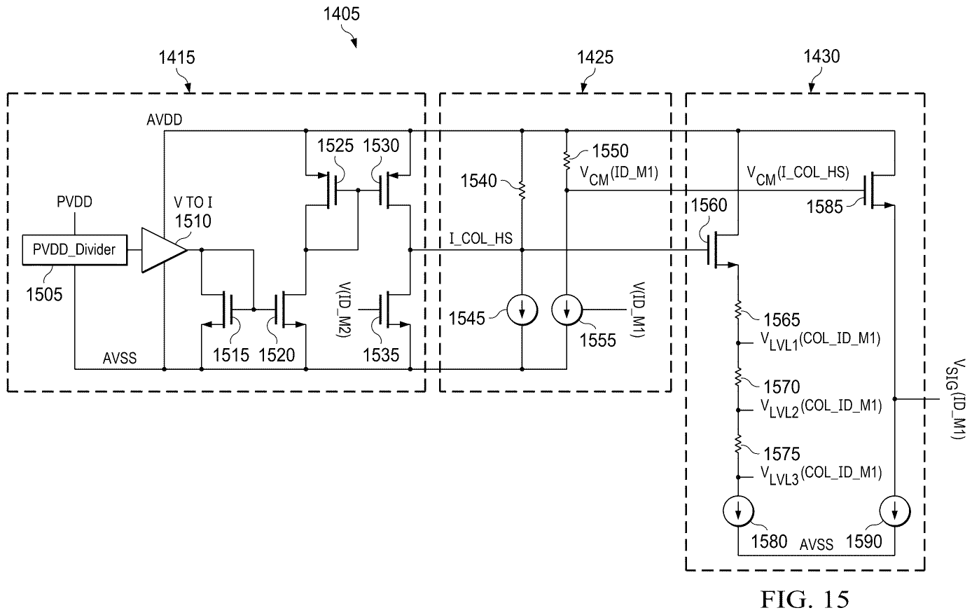

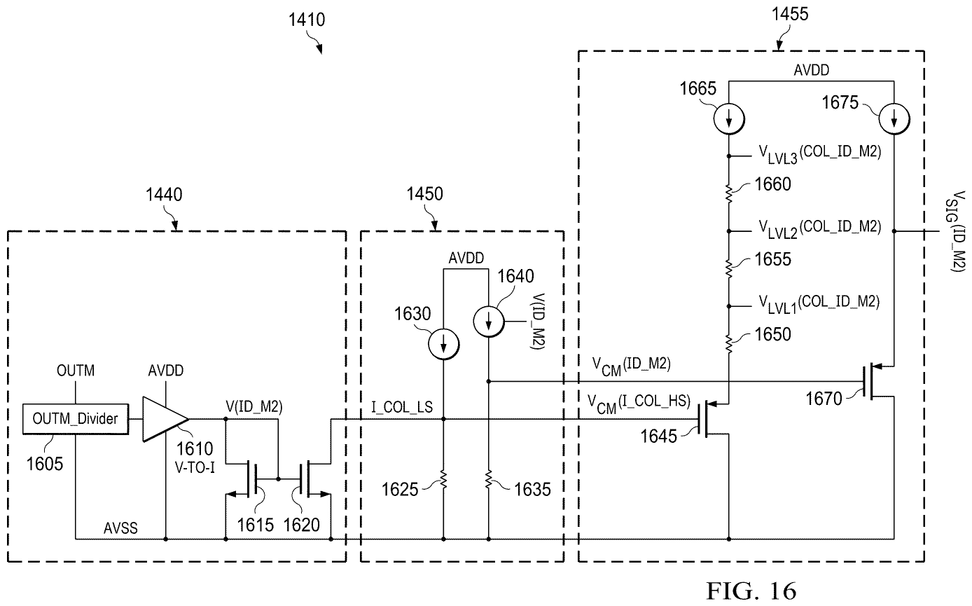

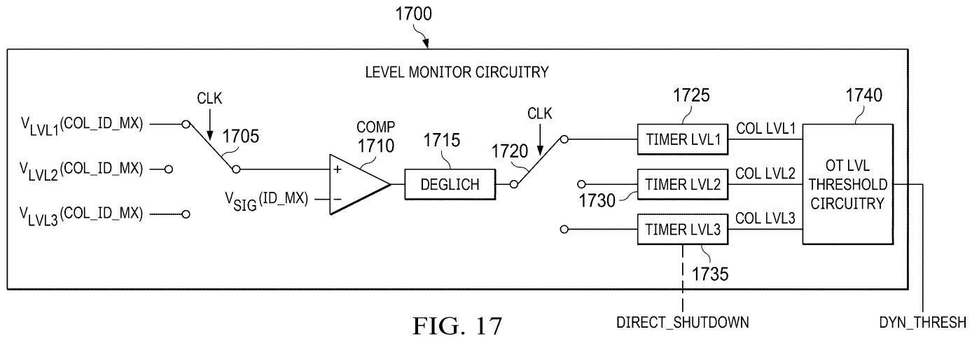

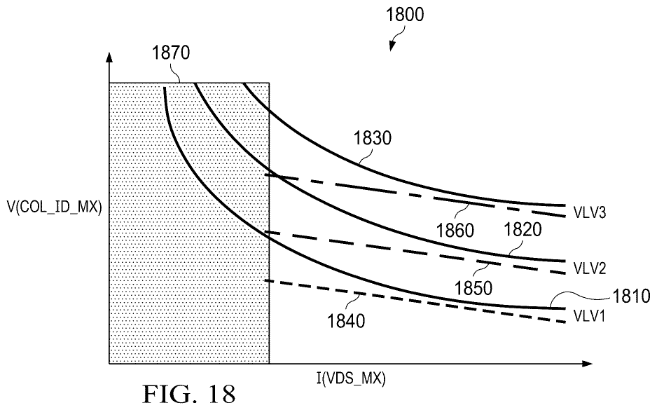

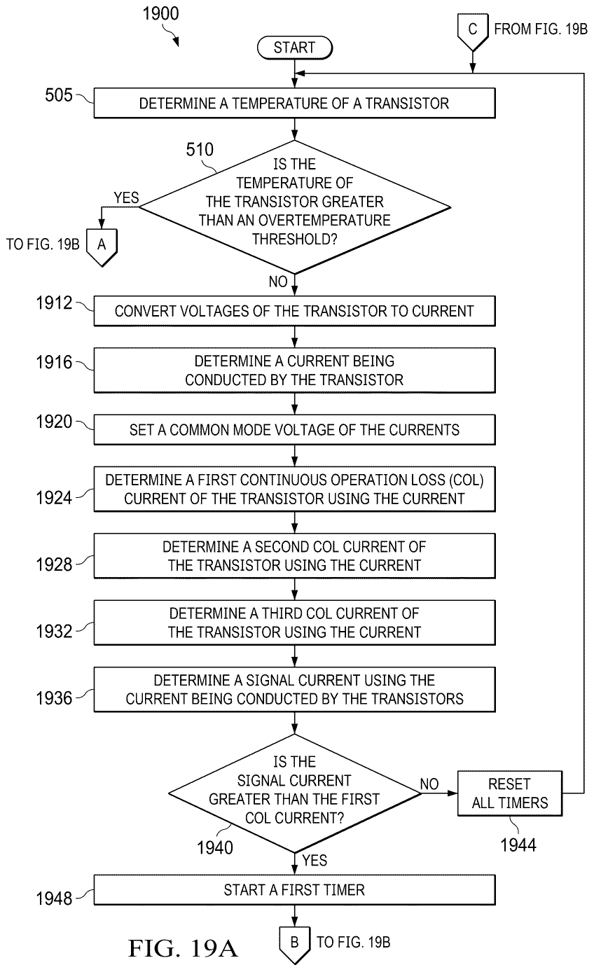

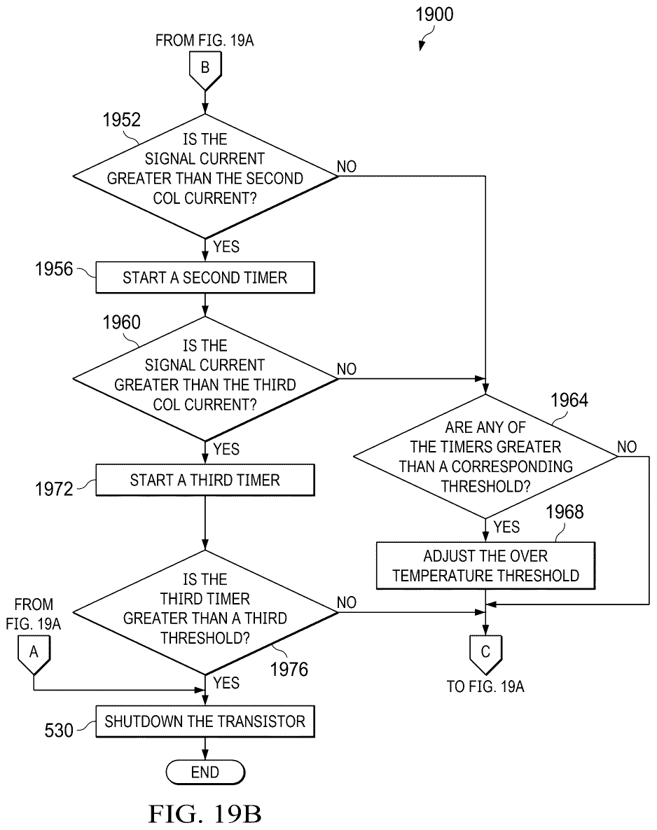

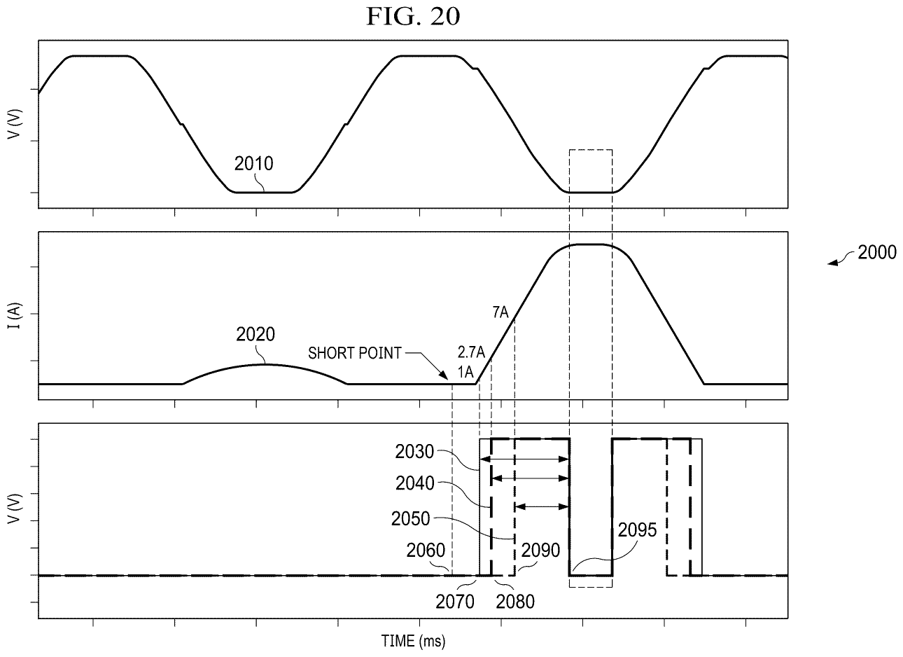

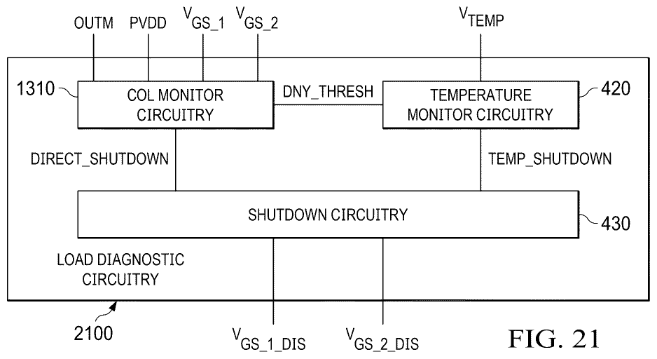

FIG. 13 illustrates a flowchart of an example method 1300 of operating a transistor, such as a transistor of power stage PS1 of audio system 100, or any transistor in a high switching noise environment. Method 1300 can be performed by a clamp circuit, such as clamp circuit 600 of FIGS. 6-11.

In operation 1302, clamp circuit 600 can detect a voltage transition event at a control terminal of the transistor. The voltage transition event can be caused by the coupling of switching noise from other devices. The detection can be performed by voltage transition detection circuit 612 and can be based on, for example, comparing the instantaneous gate voltage with an average gate voltage (as shown in FIG. 7), measuring the edge rate of the gate voltage (as shown in FIG. 8), and/or measuring the current through the transistor (as shown in FIG. 9).

In operation 1304, clamp circuit 600 can, responsive to detecting the voltage transition event, perform a clamp operation by setting the voltage of the control terminal to a reference voltage. The reference voltage can be a ground voltage or one threshold voltage above the source voltage of the transistor to disable the transistor, or an average gate voltage of the transistor to maintain the operation of the transistor, as shown in FIGS. 10A-10C. In some examples, clamp circuit 600 can disable/discontinue the clamp operation if the gate voltage of the transistor is at a maximum voltage provided by a driver of the transistor, such as amplifier 308, which indicates that the transistor is to be turned on and not to be turned off by clamp circuit 600.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, such as by an end user and/or a third party.

While the use of particular transistors is described herein, other transistors (or equivalent devices) may be used instead. For example, a p-channel field effect transistor (PFET) may be used in place of an n-channel field effect transistor (NFET) with little or no changes to the circuit. Furthermore, other types of transistors may be used, such as laterally-diffused metal-oxide semiconductor (LDMOS) FETs) and bipolar junction transistors (BJTs). Furthermore, the devices may be implemented in/over a silicon substrate (Si), a silicon carbide substrate (SIC), a gallium nitride substrate (GaN) or a gallium arsenide substrate (GaAs).

References herein to a field effect transistor (FET) being “ON” means that the conduction channel of the FET is present and drain current may flow through the FET. References herein to a FET being “OFF” means that the conduction channel is not present and drain current does not flow through the FET. A FET that is OFF, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter.

Modifications are possible in the described embodiments and examples, and other embodiments and examples are possible, within the scope of the claims, such as the examples herein below.

What is claimed is:

1. A device comprising:
a transistor having a first terminal and a control terminal;
continuous operating loss (COL) fit circuitry having an input and an output;
current sense circuitry having a first input, a second input, and an output, the first input of the current sense circuitry coupled to the first terminal of the transistor and the input of the COL fit circuitry, the second input of the current sense circuitry coupled to the control terminal of the transistor; and
comparator circuitry having a first input and a second input, the first input of the comparator circuitry coupled to the output of the COL fit circuitry, the second input of the comparator circuitry coupled of the output of the current sense circuitry.

2. The device of claim 1, further comprising voltage-to-current (V-I) circuitry having an input and an output, the input of the V-I circuitry coupled to the first terminal of the transistor, the output of the V-I circuitry coupled to the input of the COL fit circuitry.

3. The device of claim 1, wherein the comparator circuitry further has an output, and the device is further comprising:
gate-to-source voltage (VGS) detect circuitry having an input and an output, the input of the VGS detect circuitry coupled to the control terminal of the transistor; and
logic circuitry having a first input and a second input, the first input of the logic circuitry coupled to the output of the comparator circuitry, the second input of the logic circuitry coupled to the output of the VGS detect circuitry.

4. The device of claim 1, wherein the comparator circuitry further has an output, and the device further comprises timer circuitry having an input coupled to the output of the comparator circuitry.

5. The device of claim 1, wherein the COL fit circuitry includes:
voltage-to-current (V-I) circuitry having an input and an output, the input of the V-I circuitry coupled to the first terminal of the transistor;
current mirror circuitry having an input and an output, the input of the current mirror circuitry coupled to the output of the V-I circuitry; and
level divider circuitry having an input and an output, the input of the level divider circuitry coupled to the output of the current mirror circuitry, the output of the level divider circuitry coupled to the first input of the comparator circuitry.

6. The device of claim 5, wherein the comparator circuitry further has an output, the output of the level divider circuitry is a first output, the level divider circuitry further having a second output, and the device further comprising:
first switch circuitry having a first input, a second input, and an output, the first input of the first switch circuitry coupled to the first output of the level divider circuitry, the second input of the first switch circuitry coupled to the second output of the level divider circuitry, the output of the first switch circuitry coupled to the first input of the comparator circuitry;
second switch circuitry having an input, a first output, and a second output, the input of the second switch circuitry coupled to the output of the comparator circuitry;
first timer circuitry having an input coupled to the first output of the second switch circuitry; and
second timer circuitry having an input coupled to the second output of the second switch circuitry.

7. The device of claim 6, wherein the first timer circuitry further has an output, the second timer circuitry further has an output, and the device further comprising:
over temperature (OT) threshold circuitry having a first input, a second input, and an output, the first input of the OT threshold circuitry coupled to the output of the first timer circuitry, the second input of the OT threshold circuitry coupled to the output of the second timer circuitry;
temperature monitor circuitry having a first input and a second input, the first input of the temperature monitor circuitry coupled to the output of the OT threshold circuitry; and
a temperature sensor having an output coupled to the second input of the temperature monitor circuitry, the temperature sensor mechanically coupled to the transistor.

8. The device of claim 6, wherein the first timer circuitry further has an output, and the device further comprising shutdown circuitry having an input and an output, the input of the shutdown circuitry coupled to the output of the first timer circuitry, the output of the shutdown circuitry coupled to the control terminal of the transistor.

9. The device of claim 1, wherein the transistor is a first transistor, the device is further comprising:
a second transistor having a terminal;
amplifier circuitry having an output; and
filter circuitry having a first input and a second input, the first input of the filter circuitry coupled to the first terminal of the first transistor and the terminal of the second transistor, the second input of the filter circuitry coupled to the output of the amplifier circuitry.

10. A device comprising:
a transistor; and
load diagnostic circuitry coupled to the transistor, the load diagnostic circuitry configured to:
determine a drain-to-source voltage of the transistor;
determine a drain current of the transistor;
determine a continuous operating loss (COL) current of the transistor using the drain-to-source voltage;
compare the drain current to the COL current; and
determine an operating condition of the transistor responsive to the comparison.

11. The device of claim 10, wherein the transistor is a first transistor, the drain-to-source voltage is a first drain-to-source voltage, the device further comprising a second transistor, and the load diagnostic circuitry is further configured to determine a second drain-to-source voltage of the second transistor using the first drain-to-source voltage of the first transistor.

12. The device of claim 10, wherein the load diagnostic circuitry is further configured to:
start a timer responsive to the drain current being greater than the COL current; and
shutdown the transistor responsive to a determination that the timer is greater than a threshold time.

13. The device of claim 10, wherein the load diagnostic circuitry is further configured to:
start a timer responsive to the drain current being greater than the COL current; and
adjust an overtemperature threshold responsive to a determination that the timer is greater than a threshold time.

14. The device of claim 10, wherein the COL current is a first COL current, the load diagnostic circuitry further configured to:
determine a second COL current using the drain-to-source voltage, the second COL current greater than the first COL current; and
compare the drain current to the first COL current and the second COL current.

15. The device of claim 14, wherein the load diagnostic circuitry is further configured to:
start a first timer responsive to the drain current being greater than the first COL current;
start a second timer responsive to the drain current being greater than the second COL current;
adjust an overtemperature threshold responsive to a determination that the first timer is greater than a threshold time; and
shutdown the transistor responsive to a determination that the second timer is greater than a second threshold time.

16. The device of claim 10, further comprising a temperature sensor coupled to the load diagnostic circuitry, wherein the load diagnostic circuitry is further configured to:
determine a temperature of the transistor using the temperature sensor;
compare the temperature to an overtemperature threshold; and
detect thermal runaway of the transistor using the comparison.

17. A device comprising:
filter circuitry;
first amplifier circuitry coupled to the filter circuitry;
second amplifier circuitry coupled to the filter circuitry and the first amplifier circuitry; and
load diagnostic circuitry coupled to the second amplifier circuitry, the load diagnostic circuitry configured to determine a continuous operating loss (COL) current using voltages of the second amplifier circuitry.

18. The device of claim 17, wherein the second amplifier circuitry includes a transistor, and wherein the load diagnostic circuitry is further configured to:
determine a drain-to-source voltage of the transistor;
determine a drain current of the transistor; and
determine the COL current of the transistor using the drain-to-source voltage.

19. The device of claim 17, wherein the load diagnostic circuitry is further configured to:
compare the COL current to a current of the second amplifier circuitry;
start a timer based on the comparison; and
shutdown the second amplifier circuitry responsive to a determination that the timer is greater than a threshold time.

20. The device of claim 17, wherein the load diagnostic circuitry is further configured to:
compare the COL current to a current of the second amplifier circuitry;
start a timer based on the comparison; and
adjust an overtemperature threshold responsive to a determination that the timer is greater than a threshold time.

21. The device of claim 17, wherein the COL current is a first COL current, the load diagnostic circuitry further configured to:
determine a second COL current using voltages of the second amplifier circuitry, the second COL current greater than the first COL current; and
compare a current of the second amplifier circuitry to the first COL current and the second COL current.

22. The device of claim 21, wherein the load diagnostic circuitry is further configured to:
start a first timer responsive to the current of the second amplifier circuitry being greater than the first COL current;
start a second timer responsive to the current of the second amplifier circuitry being greater than the second COL current;
adjust an overtemperature threshold responsive to a determination that the first timer is greater than a threshold time; and
shutdown the second amplifier circuitry responsive to a determination that the second timer is greater than a second threshold time.

23. The device of claim 17, further comprising a temperature sensor coupled to the load diagnostic circuitry, wherein the load diagnostic circuitry is further configured to:
determine a temperature of the second amplifier circuitry using the temperature sensor;
compare the temperature to an overtemperature threshold; and
detect thermal runaway of the second amplifier circuitry using the comparison.

24. The device of claim 17, wherein the second amplifier circuitry includes a transistor, and the voltages of the second amplifier circuitry includes a drain-to-source voltage of the transistor.

25. The device of claim 17, further comprising a speaker coupled to the filter circuitry.

26. The device of claim 17, wherein the first amplifier circuitry comprises a Class-D amplifier having an output configured to be coupled to a speaker, and wherein the second amplifier circuitry is configured to be coupled to the speaker without an intervening inductor.
